(19) United States
(12) Patent Application Publication
(10) Pub. No.: US 2025/0327763 A1
(43) Pub. Date: Oct. 23, 2025

(54) DYNAMIC MULTI-WAVELENGTH AND SAMPLE VOLTAGE ATOM PROBE TOMOGRAPH FEEDBACK CONTROL SYSTEM

(71) Applicant: Government of the United States of America, as represented by the Secretary of Commerce, Gaithersburg, MD (US)

(72) Inventors: Ann Chiaramonti Debay, Boulder, CO (US); Benjamin William Caplins, Niwot, CO (US); Jacob Michael Garcia, Broomfield, CO (US); Luis Miaja Avila, Louisville, CO (US); Norman A. Sanford, Boulder, CO (US)

(21) Appl. No.: 19/202,881

(22) Filed: May 8, 2025

Related U.S. Application Data
(60) Provisional application No. 63/563,030, filed on Mar. 8, 2024.

(51) Int. Cl. G01N 23/227

(52) U.S. Cl. CPC G01N 23/227

(57) ABSTRACT

A dynamic multi-wavelength and sample voltage atom probe tomograph feedback control system includes a pulsed radiation source, an ion detector, a high voltage supply, and an analyzer. The pulsed radiation source produces first coherent light and second coherent light. The ion detector receives first emitted ions and second emitted ions from the atom probe sample. The high voltage supply produces a high voltage bias. The analyzer receives the ion signal from the ion detector and dynamically produces first pulsed radiation source control signal, second pulsed radiation source control signal, and high voltage bias control based on the ion signal. The system dynamically adjusts the optical wavelengths and sample voltage in real-time with atom probe tomography feedback by using the ion signal from the ion detector to dynamically produce first pulsed radiation source control signal, second pulsed radiation source control signal, and high voltage bias control.

### CROSS-REFERENCE TO RELATED APPLICATION

This application claims the benefit of U.S. Provisional Patent Application Ser. No. 63/563,030 (filed Mar. 8, 2024), which is herein incorporated by reference in their entirety.

### STATEMENT REGARDING FEDERALLY SPONSORED RESEARCH

This invention was made with United States Government support from the National Institute of Standards and Technology (NIST), an agency of the United States Department of Commerce. The Government has certain rights in this invention.

### BRIEF DESCRIPTION

Disclosed is a dynamic multi-wavelength and sample voltage atom probe tomograph feedback control system for dynamically adjusting optical wavelengths and sample voltage in real-time with atom probe tomography feedback, comprising: a pulsed radiation source in optical communication with an atom probe sample and in electrical communication with an analyzer, and that receives first pulsed radiation source control signal and second pulsed radiation source control signal from the analyzer, produces first coherent light based on the first pulsed radiation source control signal, produces second coherent light based on the second pulsed radiation source control signal, communicates first coherent light to the atom probe sample, communicates second coherent light to the atom probe sample, such that a wavelength, pulse rate, pulse duration, pulse duty cycle, or optical fluence of first coherent light and second coherent light, or a relative time delay between first coherent light and second coherent light, is adjusted by the first pulsed radiation source control signal and the second pulsed radiation source control signal; an ion detector in fluid communication with the atom probe sample and in electrical communication with the analyzer, and that receives first emitted ions and second emitted ions from the atom probe sample, produces ion signal from the first emitted ions and the second emitted ions, and communicates ion signal to the analyzer, such that the ion detector detects the first emitted ions and the second emitted ions as a function of a time-of-arrival, kinetic energy, or position of the first emitted ions and the second emitted ions arriving at the ion detector after the atom probe sample is subjected to the first coherent light and the second coherent light in the presence of an external electric field produced by high voltage bias; a high voltage supply in electrical communication with the atom probe sample and the analyzer, and that receives high voltage bias control from the analyzer, produces high voltage bias from the high voltage bias control, and communicates high voltage bias to the atom probe sample, such that the high voltage bias is dynamically adjusted by the high voltage bias control for optimizing, in combination with the first pulsed radiation source control signal and the second pulsed radiation source control signal, the number of first emitted ions and second emitted ions produced per time or solid angle or the total number of first emitted ions and second emitted ions, and the high voltage supply subjects the atom probe sample to the external electric field by biasing the atom probe sample relative to a counter electrode or the ion detector; and an analyzer in electrical communication with the pulsed radiation source, the ion detector, and the high voltage supply, and that receives ion signal from the ion detector, dynamically produces the first pulsed radiation source control signal, the second pulsed radiation source control signal, and the high voltage bias control based on the ion signal, such that the number of first emitted ions and second emitted ions produced per time or solid angle or the total number of first emitted ions and second emitted ions is dynamically optimized by the first pulsed radiation source control signal, the second pulsed radiation source control signal, and the high voltage bias control, and the analyzer continuously analyzes ion signal from the ion detector.

Disclosed is a process for dynamically adjusting optical wavelengths and sample voltage in real-time with atom probe tomography feedback, the process comprising: providing a sample; providing a pulsed radiation source in optical communication with the sample; providing an ion detector in fluid communication with the sample; providing a high voltage supply in electrical communication with the sample; and providing an analyzer in electrical communication with the pulsed radiation source, the ion detector, and the high voltage supply.

### BRIEF DESCRIPTION OF THE DRAWINGS

The following description cannot be considered limiting in any way. Various objectives, features, and advantages of the disclosed subject matter can be more fully appreciated with reference to the following detailed description of the disclosed subject matter when considered in connection with the following drawings, in which like reference numerals identify like elements.

FIG. 1 shows, according to some embodiments, a dynamic multi-wavelength and sample voltage atom probe tomograph feedback control system 200.

FIG. 2 shows, according to some embodiments, a dynamic multi-wavelength and sample voltage atom probe tomograph feedback control system 200.

FIG. 3 shows, according to some embodiments, a computing system for control and analysis.

FIG. 4 shows, according to some embodiments, a graph of mass-to-charge versus ion sequence, a graph of high voltage bias 228 versus time, a graph of ion detection rate versus time, and a graph of fluence versus time for an atom probe sample 202 shown in the figure.

FIG. 5 shows, according to some embodiments, a graph of mass-to-charge versus ion sequence, a graph of high voltage bias 228 versus time, a graph of ion detection rate versus time, and a graph of fluence versus time for an atom probe sample 202 shown in the figure.

FIG. 6 shows, according to some embodiments, a graph of mass-to-charge versus ion sequence, a graph of high voltage bias 228 versus time, a graph of ion detection rate versus time, and a graph of fluence versus time for an atom probe sample 202 shown in the figure.

FIG. 7 shows, according to some embodiments, a graph of mass-to-charge versus ion sequence, a graph of high voltage bias 228 versus time, a graph of ion detection rate versus time, a graph of fluence versus time, and a graph of time delay versus time for an atom probe sample 202 shown in the figure.

FIG. 8 shows, according to some embodiments, comparative graphs from two constant evaporation rate experiments on a specimen using different laser wavelengths (λ1 and λ2), illustrating the corresponding changes in specimen voltage and measured background signal.

FIG. 9 shows, according to some embodiments, graphs of experimental results using two different laser wavelengths on a specimen with a non-constant radius, plotting voltage, ion detection rate, fluence, and background signal against experiment time to demonstrate the benefits of wavelength selection.

### DETAILED DESCRIPTION

A detailed description of one or more embodiments is presented herein by way of exemplification and not limitation.

Conventional atom probe tomography systems typically use a single narrow-band, coherent wavelength (e.g., single color laser) of light. This can lead to problems with accuracy and precision, as the system is not able to account for the different evaporation fields or ionization energies of the atoms in the sample. Moreover, specimens that include different elements, phases, substances, or materials are difficult to analyze in conventional atom probe tomography since there is often significant heterogeneity in optical, thermal, and electrical properties between the chemically distinct regions. The optimal laser wavelength used to trigger field ion evaporation in atom probe tomography (APT) seems to be material dependent. Different wavelength ranges appear to be optimal for each component in heterogeneous samples, and these run conditions frequently have insufficient overlap to allow for a successful outcome.

For APT, all regions of such a structure must yield successful analysis. Wavelength-agile APT instrumentation with two or more coincident pulses of differing wavelength are utilized so that all regions of a complex specimen can yield successful results since the tool will be configured to dynamically deliver coherent wavelength(s) most suitable to the region or regions of a specimen under examination. The tuning of each laser pulse intensity and timing delay may result in highly improved APT data collection and sample survivability through optimization of the specimen response (e.g., voltage, ions/time, ions/solid angle, total #ions, etc.) as it transitions between heterogeneous regions.

Dynamic multi-wavelength and sample voltage atom probe tomograph feedback control system 200 overcomes these limitations by using multiple wavelengths of light and a variable sample voltage. This allows the system to measure the composition of the sample more accurately and precisely. Dynamic multi-wavelength and sample voltage atom probe tomograph feedback control system 200 is a significant improvement over conventional systems. The system is more accurate and more precise than conventional systems. The system is also more versatile than conventional systems, as it can be used to measure the composition of a wide variety of samples. Further, dynamic multi-wavelength and sample voltage atom probe tomograph feedback control system 200 provides efficient and uniform field evaporation and detection of the constituent chemical elements of a specimen comprised of more than one element, phase, substance, or material. Dynamic multi-wavelength and sample voltage atom probe tomograph feedback control system 200 illuminates an atom probe tomography specimen with more than one wavelength of pulsed electromagnetic radiation and dynamically tunes the intensity and relative time delay of these multiple wavelengths in order to optimize a specimen response in real time. It is contemplated that some specimens may run optimally pulsed voltage only mode, or with only a single wavelength.

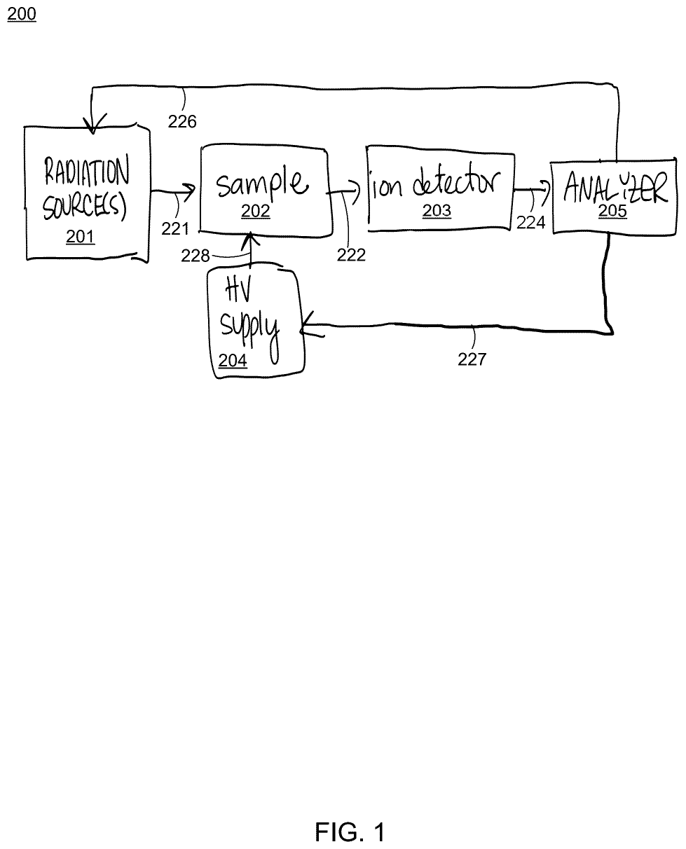

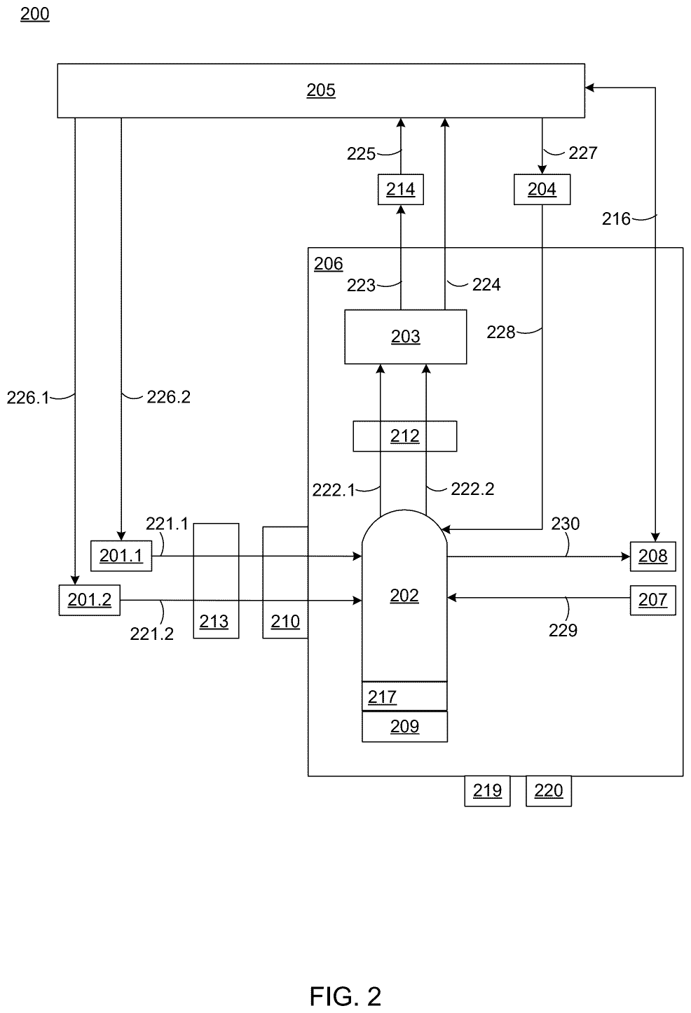

Dynamic multi-wavelength and sample voltage atom probe tomograph feedback control system 200 dynamically adjusts optical wavelengths and sample voltage in real-time with atom probe tomography feedback. In an embodiment, with reference to FIG. 1, and FIG. 2, dynamic multi-wavelength and sample voltage atom probe tomograph feedback control system 200 for dynamically adjusting optical wavelengths and sample voltage in real-time with atom probe tomography feedback includes: pulsed radiation source 201 in optical communication with atom probe sample 202 and in electrical communication with analyzer 205, such that pulsed radiation source 201 receives first pulsed radiation source control signal 226 and second pulsed radiation source control signal 226 from analyzer 205, produces first coherent light 221 based on first pulsed radiation source control signal 226, produces second coherent light 221 based on second pulsed radiation source control signal 226, communicates first coherent light 221 to atom probe sample 202, and communicates second coherent light 221 to atom probe sample 202, such that a wavelength, pulse rate, pulse duration, pulse duty cycle, or optical fluence of first coherent light 221 and second coherent light 221, or a relative time delay between first coherent light 221 and second coherent light 221, is adjusted by first pulsed radiation source control signal 226 and second pulsed radiation source control signal 226; ion detector 203 in fluid communication with atom probe sample 202 and in electrical communication with analyzer 205, the ion detector 203 receiving first emitted ions 222 and second emitted ions 222 from atom probe sample 202, the ion detector 203 producing ion signal 224 from first emitted ions 222 and second emitted ions 222, the ion detector 203 communicating ion signal 224 to analyzer 205, such that ion detector 203 detects first emitted ions 222 and second emitted ions 222 as a function of a time-of-arrival, kinetic energy, and/or position of first emitted ions 222 and second emitted ions 222 arriving at ion detector 203 after atom probe sample 202 is subjected to first coherent light 221 and second coherent light 221 in the presence of an external electric field produced by high voltage bias 228; high voltage supply 204 in electrical communication with atom probe sample 202 and analyzer 205, high voltage supply 204 receiving high voltage bias control 227 from analyzer 205, high voltage supply 204 producing high voltage bias 228 from high voltage bias control 227, high voltage supply 204 communicating high voltage bias 228 to atom probe sample 202, such that high voltage bias 228 is dynamically adjusted by high voltage bias control 227 for optimizing, in combination with first pulsed radiation source control signal 226 and second pulsed radiation source control signal 226, the number of first emitted ions 222 and second emitted ions 222 produced per time or solid angle or the total number of first emitted ions 222 and second emitted ions 222, high voltage supply 204 subjects atom probe sample 202 to the external electric field by biasing atom probe sample 202 relative to a counter electrode or ion detector 203; and analyzer 205 in electrical communication with pulsed radiation source 201, ion detector 203, and high voltage supply 204, the analyzer 205 receiving ion signal 224 from ion detector 203, the analyzer 205 dynamically producing first pulsed radiation source control signal 226, second pulsed radiation source control signal 226, and high voltage bias control 227 based on ion signal 224, such that the number of first emitted ions 222 and second emitted ions 222 produced per time or solid angle or the total number of first emitted ions 222 and second emitted ions 222 is dynamically optimized by first pulsed radiation source control signal 226, second pulsed radiation source control signal 226, and high voltage bias control 227, and analyzer 205 continuously analyzes ion signal 224 from ion detector 203.

In an embodiment, dynamic multi-wavelength and sample voltage atom probe tomograph feedback control system 200 includes atom probe sample 202 in optical communication with pulsed radiation source 201 and in electrical communication with high voltage supply 204 and in fluid communication with ion detector 203, atom probe sample 202 receiving first coherent light 221 and second coherent light 221 from pulsed radiation source 201, atom probe sample 202 receiving high voltage bias 228 from high voltage supply 204 so that atom probe sample 202 is voltage-biased with a high electric field strength between ion detector 203, atom probe sample 202 producing first emitted ions 222 in response to interaction with first coherent light 221 in presence of high voltage bias 228, atom probe sample 202 producing second emitted ions 222 in response to interaction with second coherent light 221 in presence of high voltage bias 228, and atom probe sample 202 communicating first emitted ions 222 and second emitted ions 222 to ion detector 203, such that atom probe sample 202 is subjected to field ion emission where the number of first emitted ions 222 and second emitted ions 222 produced per time or solid angle or the total number of first emitted ions 222 and second emitted ions 222 is dynamically optimized by first pulsed radiation source control signal 226, second pulsed radiation source control signal 226, and high voltage bias control 227.

In an embodiment, dynamic multi-wavelength and sample voltage atom probe tomograph feedback control system 200 includes vacuum chamber 206 in which is disposed atom probe sample 202 and on which is disposed ion detector 203, and is in optical communication with pulsed radiation source 201, in mechanical communication with atom probe sample 202 and ion detector 203, in electrical communication with high voltage supply 204 and analyzer 205, and that provides an evacuated gas atmosphere for atom probe sample 202 and ion detector 203.

In an embodiment, dynamic multi-wavelength and sample voltage atom probe tomograph feedback control system 200 includes electron source 207 that produces electron beam 229 and communicates electron beam 229 to atom probe sample 202, such that atom probe sample 202 produces scattered electrons 230 in response to receipt of electron beam 229, wherein scattered electrons 230 provides structural information about atom probe sample 202; and electron detector 208 in electrical communication with analyzer 205 and that receives scattered electrons 230 from atom probe sample 202 in response to atom probe sample 202 received electron beam 229 from electron source 207, produces electron data 216 from scattered electrons 230, and communicates electron data 216 to analyzer 205.

In an embodiment, dynamic multi-wavelength and sample voltage atom probe tomograph feedback control system 200 includes sample stage 209 on which is disposed atom probe sample 202 and is in mechanical communication with atom probe sample 202 and that provides for positional manipulation of atom probe sample 202 relative to ion detector 203, first coherent light 221, or second coherent light 221.

In an embodiment, dynamic multi-wavelength and sample voltage atom probe tomograph feedback control system 200 includes coupler 210 in optical communication with pulsed radiation source 201 and atom probe sample 202, and that receives first coherent light 221 and second coherent light 221 from pulsed radiation source 201 and communicates first coherent light 221 and second coherent light 221 to atom probe sample 202 in vacuum chamber 206 by optically coupling atom probe sample 202 to pulsed radiation source 201.

In an embodiment, dynamic multi-wavelength and sample voltage atom probe tomograph feedback control system 200 includes ion optic 212 that is interposed between atom probe sample 202 and ion detector 203, such that ion optic 212 extracts and/or focuses first emitted ions 222 and second emitted ions 222 from atom probe sample 202 and communicates first emitted ions 222 and second emitted ions 222 to ion detector 203, wherein ion optic 212 comprises an extraction electrode, a counter electrode, Einzel lens, or other suitably engineered ion optic.

In an embodiment, dynamic multi-wavelength and sample voltage atom probe tomograph feedback control system 200 includes pulsed radiation source optic 213 in optical communication with pulsed radiation source 201 and atom probe sample 202 and that receives first coherent light 221 and second coherent light 221 from pulsed radiation source 201 and communicates first coherent light 221 and second coherent light 221 to atom probe sample 202, such that pulsed radiation source optic 213 comprises e.g. a mirror, zone plate, multilayer mirror, or a lens.

In an embodiment, dynamic multi-wavelength and sample voltage atom probe tomograph feedback control system 200 includes electron data 216 that is communicated between electron detector 208 and analyzer 205 and comprises an electron micrograph or electron diffraction pattern of scattered electrons 230 or a control signal to control electron detector 208.

In an embodiment, dynamic multi-wavelength and sample voltage atom probe tomograph feedback control system 200 includes cryostat 217 on which is disposed atom probe sample 202 in thermal and mechanical communication with atom probe stage 209 and is in thermal and mechanical communication with atom probe sample 202 and that cools and temperature controls atom probe sample 202 and atom probe stage 209.

In an embodiment, dynamic multi-wavelength and sample voltage atom probe tomograph feedback control system 200 includes timing electronics 218 disposed in analyzer 205 and includes a time-to-digital convertor for synchronizing temporal performance of dynamic multi-wavelength and sample voltage atom probe tomograph feedback control system 200.

In an embodiment, dynamic multi-wavelength and sample voltage atom probe tomograph feedback control system 200 includes vacuum gauge 219 disposed on vacuum chamber 206 and in fluid communication with vacuum chamber 206 and that measures a pressure of vacuum chamber 206. In an embodiment, dynamic multi-wavelength and sample voltage atom probe tomograph feedback control system 200 includes vacuum valves 220 disposed on vacuum chamber 206 and in mechanical communication with vacuum chamber 206 and that provides access to an interior of vacuum chamber 206 for arranging atom probe sample 202 in vacuum chamber 206.

In an embodiment, dynamic multi-wavelength and sample voltage atom probe tomograph feedback control system 200 includes coherent light 221 that is produced by pulsed radiation source 201 and is communicated from pulsed radiation source 201 to atom probe sample 202 to produce emitted ions 222 from atoms of atom probe sample 202.

In an embodiment, dynamic multi-wavelength and sample voltage atom probe tomograph feedback control system 200 includes field emitted ions 222 that are produced by atom probe sample 202 from atoms in atom probe sample 202 and are communicated from atom probe sample 202 to ion detector 203.

In an embodiment, dynamic multi-wavelength and sample voltage atom probe tomograph feedback control system 200 includes ion signal 224 that is produced by ion detector 203 from receipt of emitted ions 222 by ion detector 203 and communicated from ion detector 203 to analyzer 205.

In an embodiment, dynamic multi-wavelength and sample voltage atom probe tomograph feedback control system 200 includes pulsed radiation source control signal 226 that is dynamically produced by analyzer 205 from analysis of ion signal 224, is communicated from analyzer 205 to pulsed radiation source 201, and controls the wavelength, pulse rate, pulse duration, pulse duty cycle, time delay between pulses, or optical fluence of first coherent light 221 and second coherent light 221, or a relative time delay between first coherent light 221 and second coherent light 221.

In an embodiment, dynamic multi-wavelength and sample voltage atom probe tomograph feedback control system 200 includes: high voltage bias control 227 that is dynamically produced by analyzer 205 from analysis of ion signal 224, is communicated from analyzer 205 to high voltage supply 204, and controls high voltage bias 228 supplied to atom probe sample 202 through electrical communication with sample stage 209 from high voltage supply 204; and high voltage bias 228 that is produced by high voltage supply 204, communicated from high voltage supply 204 to atom probe sample 202 through electrical communication with sample stage 209, and received by atom probe sample 202 to electrically bias atom probe sample 202 and create the electric field in which first emitted ions 222 and second emitted ions 222 are made.

In an embodiment, dynamic multi-wavelength and sample voltage atom probe tomograph feedback control system 200 includes: electron beam 229 that is produced by electron source 207, communicated from electron source 207 to atom probe sample 202, received by atom probe sample 202, and produces scattered electrons 230 from interaction with atom probe sample 202; and scattered electrons 230 that are produced by atom probe sample 202 from electron beam 229, communicated from atom probe sample 202 to electron detector 208, and received by electron detector 208.

According to an embodiment, dynamic multi-wavelength and sample voltage atom probe tomograph feedback control system 200 includes: pulsed radiation source(s) to: produce radiation; subject a sample specimen to the radiation source(s); field ionize or photoionize a plurality of atoms of the sample; and form field ions or photoions from the atoms subject to the radiation, the ions being field desorbed or thermally emitted from the sample in response to the sample being subjected to the radiation in a presence of an external electric field. Intensity or fluence, pulse rate, pulse duration, and pulse duty cycle, time delay between pulses, of radiation sources at the specimen location can be varied dynamically, e.g., by direct electronic or mechanical control of the radiation sources; optical filters or optical attenuators that regulate the strength or intensity of the radiation that illuminate the specimen, steering and manipulating the radiation to illuminate the specimen under electronic or mechanical control. Pulsed radiation source(s) can be, e.g., white light or broadband electromagnetic radiation with output that is or can be dynamically spectrally filtered (e.g., using a prism, diffraction grating, and the like) to select two or more wavelengths of interest; The radiation sources can be discrete, separate, nominally monochromatic sources (e.g., “lasers”). Radiation sources can be a frequency band source (e.g., obtained via high harmonic generation). A sample specimen is subject to field ion emission interaction of light from radiation sources and/or high electric field strength. An ion detector detects the emitted ions as a function of a time-of-arrival or kinetic energy of the ions arriving at the ion detector after the sample is subjected to the radiation in the presence of an external electric field or as a function of a position of the ions at the detector. A high voltage (HV) supply subjects the specimen to an external electric field by biasing the sample stage 209 relative to a counter electrode or the ion detector. An analyzer continuously analyzes data from the ion detector. The analyzer is in electrical communication with the ion detector, high voltage supply, and radiation sources. The analyzer receives ion data and voltage data and continuously analyzes the data to optimize a specimen response. The analyzer can control the high voltage supply or the radiation sources (intensity and relative time delay or duty cycle) to optimize the specimen response (e.g., minimize voltage, maximize ion detection rate, maximize ions detected per solid angle, minimize multiple hits, minimize background signal, and the like) by manipulating the inputs (e.g., adjusting the magnitude of the HV output, HV duty cycle, intensity of radiation sources, duty cycle of radiation sources, and the like).

Dynamic multi-wavelength and sample voltage atom probe tomograph feedback control system 200 can be made of various elements and components that can be assembled together or fabricated. Elements of dynamic multi-wavelength and sample voltage atom probe tomograph feedback control system 200 can be various sizes and shapes. Elements of dynamic multi-wavelength and sample voltage atom probe tomograph feedback control system 200 can be made of a material that is physically or chemically resilient in an environment in which dynamic multi-wavelength and sample voltage atom probe tomograph feedback control system 200 is disposed. Exemplary materials include metals, ceramics, thermoplastics, glass, semiconductors, and the like. The elements of dynamic multi-wavelength and sample voltage atom probe tomograph feedback control system 200 can be made of the same or different material and can be monolithic in a single physical body or can be separate members that are physically joined.

Dynamic multi-wavelength and sample voltage atom probe tomograph feedback control system 200 is a device that uses a pulsed radiation source, an ion detector, a high voltage supply, and an analyzer to produce a mass spectrum and three-dimensional point cloud representation of the atoms in the sample. The pulsed radiation source produces coherent light, e.g., of two different wavelengths, which are used to excite the sample. The ion detector detects the ions that are emitted from the sample, and the high voltage supply applies a voltage to the sample. The analyzer uses the information from the ion detector and the high voltage supply to optimize a specimen response through control of the pulsed radiation sources and high voltage supply. Dynamic multi-wavelength and sample voltage atom probe tomograph feedback control system 200 has several advantages over other atom probe tomographs. It is able to analyze samples that are difficult to analyze with other atom probe tomographs, such as samples that are composed of multiple elements, phases, substances, or materials Dynamic multi-wavelength and sample voltage atom probe tomograph feedback control system 200 can be used to study a variety of materials, including metals, insulators, semiconductors, organic materials, and biological materials. Atom probe sample 202 can be single phase or multiple phases. Atom probe sample 202 can be homogeneous or heterogeneous. Atom probe can study chemical gradients across arbitrarily shaped and oriented interfaces. Dynamic multi-wavelength and sample voltage atom probe tomograph feedback control system 200 is a powerful tool for the study of materials at the atomic level.

Pulsed radiation source 201 can be a laser or set of lasers that produces coherent light of a specific wavelength. The laser can be a pulsed laser that emits light in short bursts or pulses. The wavelength of the light can be adjusted to control the absorption of the light by the sample. The pulse rate, pulse duration, pulse duty cycle, or optical fluence of the light can also be adjusted to control the amount of light that is incident on the sample. The relative time delay between the pulses can also be adjusted. Pulsed radiation source 201 is used in conjunction with an atom probe tomography system to create three-dimensional point cloud datasets representative of the individual atoms in a sample by field emitting atoms from a sample one at a time and then measuring the time-of-flight of the ions formed from the atoms as they travel to a detector. The time-of-flight of the ions is used to determine the isotopic identity of the atoms in the sample. It should be appreciated that pulsed radiation source 201 can include a plurality of individual sources, e.g., first pulsed radiation source 201.1, second pulsed radiation source 201.2, . . . , n-th pulsed radiation source 201.n (wherein n is an arbitrary integer), that individually produce their own coherent light 221 (e.g., first coherent light 221.1, second coherent light 221.2, . . . , n-th coherent light 221.n (wherein n is an arbitrary integer)) under individual dynamic adjustment by separate pulsed radiation source control signal 226 (e.g., first pulsed radiation source control signal 226.1, second pulsed radiation source control signal 226.2, . . . , n-th pulsed radiation source control signal 226.n (wherein n is an arbitrary integer)).

Atom probe sample 202 can be a small, typically sub-micrometer, piece of material that is analyzed by atom probe tomography. The sample can be prepared by cutting a thin slice from a larger piece of material, and then polishing the sample into a needle shape electrochemically or using a focused ion beam microscope. The sample is then mounted in a holder, which is in mechanical contact with the sample stage 209 that is compatible with the atom probe tomography system. Atom probe sample 202 can be electrically conductive, semiconductive, or even insulating. Atom probe sample 202 can be a composite material. Atom probe sample 202 should also be stable under the high vacuum conditions that are involved in atom probe tomography. Atom probe sample 202 can be free of contaminants, such as water or oil, which can interfere with the analysis. The choice of material depends on the type of material that is being analyzed and the desired resolution of the analysis.

Ion detector 203 is a device that detects ions emitted from atom probe sample 202. It can be made up of a series of electrodes (e.g., similar to dynodes of an electron multiplier) that are arranged in a vacuum chamber, e.g., typically a microchannel plate and the like. The microchannel plate is often combined with a position sensitive detector, e.g., delay line detector. Ion detector 203 measures the number of emitted ions 222 emitted from atom probe sample 202. Ion detector measures the location of emitted ions on the detector. This information is combined to reconstruct a three-dimensional point cloud representation of the atoms in atom probe sample 202. Ion detector 203 can detect emitted ions 222 with a range of masses and energies, detect emitted ions 222 with a high degree of time and spatial resolution, and can operate in a vacuum environment.

High voltage supply 204 is a device that provides high voltage bias 228 to atom probe sample 202 through electrical contact with the sample stage 209. High voltage bias 228 is used to reduce the barrier to field ion emission as well as accelerate field ions 222 that are emitted from atom probe sample 202. High voltage supply 204 can be able to provide a high voltage with a high degree of stability. The high voltage can be stable so that emitted ions 222 from atom probe sample 202 are accelerated with a narrow kinetic energy distribution. High voltage supply 204 can also be able to provide a high voltage with a high degree of accuracy. The high voltage can be accurate so that the ions that are emitted from atom probe sample 202 are accelerated with a narrow range of kinetic energy. High voltage supply 204 can be operated in a pulsed mode. The high voltage is increased for a short period of time and then brought back down to the standing level, to minimize emission of ions not correlated with the voltage pulse as well as minimize spurious field ionization of residual gas in the vacuum chamber 206. In an embodiment, high voltage supply 204 is operated in a feedback mode, wherein high voltage bias 228 is dynamically adjusted by high voltage bias control 227 based on ion signal 224 from ion detector 203 to optimize the number of emitted ions 222 that are emitted from atom probe sample 202.

Analyzer 205 can be a processor-based device that receives ion signal 224 from ion detector 203 and dynamically produces first pulsed radiation source control signal 226, second pulsed radiation source control signal 226, and high voltage bias control 227 based on ion signal 224. The analyzer 205 can include a processor, memory, and input/output (I/O) devices. The processor is responsible for executing instructions stored in the memory. The memory stores the instructions and data that the processor needs to execute. The I/O devices allow the analyzer 205 to communicate with other devices, such as pulsed radiation source 201, ion detector 203, and high voltage supply 204. The analyzer 205 includes a number of software modules or hardware (e.g., field programmable gate arrays) that are responsible for different tasks. An ion signal processing module processes ion signal 224 from ion detector 203. A pulsed radiation source control module generates the first pulsed radiation source control signal 226 and the second pulsed radiation source control signal 226. A high voltage bias control module generates high voltage bias control 227.

Vacuum chamber 206 is a sealed enclosure that is maintained at a low pressure. This low pressure prevents atom probe sample 202 from being contaminated by extraneous gas atoms or molecules and provides a sufficient mean free path for a flight length of emitted ions 222 from atom probe sample 202 to ion detector 203. It also prevents undesired field ionization of residual chamber gasses. Vacuum chamber 206 can be made of stainless steel, aluminum, or other suitably durable vacuum-compatible material and is equipped with a number of ports for the introduction of gases, the removal of gases, exchange of atom probe sample 202 and ion detector 203 and connection of electrical and optical cables. Vacuum chamber 206 is also equipped with a number of sensors that monitor the pressure, temperature, and cleanliness of the chamber. Vacuum chamber 206 can be operated at a pressure of 10⁻⁶ to 10⁻⁹ Pa or lower pressure, e.g., ultra-high vacuum. This pressure level prevents field ionization of residual chamber gas by the atom probe sample 202 subject to high electric field by the high voltage supply 204 that would contribute to the background signal. It also prevents the atom probe sample 202 from being contaminated or scattering emitted ions 222 that are emitted from atom probe sample 202, making it difficult to obtain accurate measurements. Vacuum chamber 206 can be equipped with sensors that monitor the pressure and cleanliness of the chamber. These sensors are used to ensure that the chamber is operating within the proper parameters. Vacuum gauge 219 is a pressure sensor that ensures that the chamber is at the desired pressure The cleanliness sensor (e.g., a residual gas analyzer) can ensure that the chamber is free of contaminants.

Electron source 207 can be a thermionic or field emission source. The electrons are then accelerated by a high voltage bias and focused into a beam by a series of lenses. The electron beam is then communicated from electron source 207 to atom probe sample 202, where it interacts with the sample and produces scattered electrons 230. Scattered electrons 230 are then communicated from atom probe sample 202 to electron detector 208, where they are detected and analyzed. Electron source 207 can be made of tungsten or ceramic (e.g., LaB6), which has a high melting point and appropriate work function. The high voltage bias that accelerates the electrons can be in the range of 1-100 kV or more. The lenses that focus the electron beam are magnetic or electrostatic, and they are designed to produce a beam with a small spot size and/or a high degree of collimation.

Electron detector 208 is a device that detects electrons that are scattered from or by atom probe sample 202. It can be used as an electron microscope to image the surface of a sample. Electron detector 208 can also be used to measure the angle of scattered electrons (e.g., the Fraunhofer diffraction pattern), which can provide information about the crystallographic phase of the sample. Electron detector 208 has a number of properties that make it useful for a variety of applications. It is sensitive to a wide range of electron energies, making it suitable for use with a variety of electron microscopes. It is also relatively fast, making it possible to image samples in real time.

Sample stage 209 can be a platform that supports atom probe sample 202 and allows for its precise positioning and orientation. It can be made of a material that is compatible with the vacuum chamber 206, such as a metal or ceramic. Sample stage 209 can be mounted on a manipulator that allows for its movement in three dimensions. The manipulator can be controlled by a computer, which allows for the precise positioning of atom probe sample 202. Sample stage 209 can withstand the high vacuum conditions that are involved in atom probe tomography. It can withstand the cold temperatures generated during the atom probe process. Sample stage 209 can maintain atom probe sample 202 in a stable position during the atom probe process. It should be appreciated that sample stage 209 mechanically couples atom probe sample 202 to vacuum chamber 206. Sample stage 209 thermally couples the atom probe sample 202 with the cryostat 217. Sample stage 209 electrically couples the atom probe sample 202 with the high voltage supply 204.

Coupler 210 is a device that couples pulsed radiation source 201 to atom probe sample 202. The coupler helps to ensure that all, a substantial portion, or a selected amount of coherent light 221 from pulsed radiation source 201 is communicated to and received by atom probe sample 202. Coupler 210 can be under vacuum. Coupler 210 can improve the accuracy and precision of the atom probe tomograph feedback control system 200.

Ion optic 212 is a device that is used to focus and deflect emitted ions 222 that are emitted from atom probe sample 202 Ion optic 212 can be used to control the spatial distribution of the ions that are emitted from the atom probe sample, which can be used to improve the resolution of the atom probe tomography data. Ion optic 212 has stable performance so that the focus and deflection of emitted ions 222 are not affected by changes in the environment, such as temperature and pressure to ensure that the atom probe tomography data are accurate and reproducible.

Pulsed radiation source optic 213 is a device that is used to focus and direct pulsed radiation source 201 onto atom probe sample 202. Pulsed radiation source optic 213 can be mounted in a holder that allows it to be aligned with atom probe sample 202. Pulsed radiation source optic 213 can be used in conjunction with pulsed radiation source 201 that emits a beam of light that is pulsed at a high frequency. Pulsed radiation source optic 213 is used to focus the pulsed beam of light onto atom probe sample 202.

Electron data 216 are a collection of data points that represent the number of scattered electrons 230 detected by electron detector 208 as a function of the electron energy 231, trajectories, angles, momentum, and the like. Electron data 216 can be used to determine the morphology of atom probe sample 202, as well as the crystallographic structure of atom probe sample 202. Electron data 216 can be collected in a number of ways. One common method is to use a scanning electron microscope (SEM). In an SEM, a convergent beam of electrons is scanned across the surface of atom probe sample 202. The electrons interact with the atoms in atom probe sample 202, and some of the electrons are scattered back to the electron detector 208. The electron detector 208 detects the scattered electrons and uses them to create an image of the surface of atom probe sample 202

Cryostat 217 is a vacuum-compatible device that is used to maintain a low temperature for atom probe sample 202 through thermal contact with the atom probe sample stage 209. Cryostat 217 can keep atom probe sample 202 and atom probe sample stage 209 at a low temperature to prevent significant surface diffusion during analysis as well as prevent stochastic field ion emission uncorrelated with the radiation or voltage pulse.

Timing electronics 218 are used to control the timing of pulsed radiation source 201, ion detector 203, and high voltage supply 204. Timing electronics 218 can include a clock, a pulse generator, a sequencer, analog time to digital convertor, and the like. The clock generates a clock signal that is used to control the timing of pulsed radiation source 201, ion detector 203, and high voltage supply 204. The pulse generator generates a pulse signal that is used to control pulsed radiation source 201. The sequencer generates a sequence of control signals that are used to control the ion detector 203 and high voltage supply 204. Timing electronics 218 ensure that pulsed radiation source 201, the ion detector 203, and high voltage supply 204 are operated in a synchronized manner so that dynamic multi-wavelength and sample voltage atom probe tomograph feedback control system 200 produces accurate time of flight results.

Vacuum gauge 219 is a device that measure the pressure of a gas in vacuum chamber 206. There are many different types of vacuum gauges. Exemplary vacuum gauges include cold cathode gauges, ionization gauges, Penning gauges, and thermocouple gauges.

Vacuum valves 220 Control access to the vacuum chamber 206. They are typically made of metal and have a number of different ports that allow for the connection of various components, such as the sample chamber or load lock. The vacuum valves 220 maintain a high vacuum in the atom probe tomograph.

Coherent light is light that has a consistent spatial or temporal phase relationship between its waves. Coherent light can be produced by lasers, and it has a number of properties that make it useful for a variety of applications. Coherent light can be focused to a very small point. This makes it ideal for use in microscopy and other applications where high-resolution imaging is required. Coherent light can also be used to create interference patterns, which can be used to measure distances and other physical properties. In the context of dynamic multi-wavelength and sample voltage atom probe tomograph feedback control system 200, coherent light is used to interact with atoms in atom probe sample 202. This interaction in presence of high voltage bias 228 causes the atoms in the sample to field ionize and form field ions 222, which are then detected by ion detector 203. Ion signal 224 is then analyzed by the analyzer 205, which uses it to control pulsed radiation source control signal 226, second pulsed radiation source control signal 226, and high voltage bias control 227. This feedback loop allows the system to dynamically adjust the optical wavelengths and sample voltage in real-time, which results in improved atom probe tomography data. Coherent light 221 can be of a short enough pulse duration to avoid significantly heating the sample. Coherent light 221 may be of a uniform intensity across the sample. Coherent light 221 should be of a stable intensity over time. Coherent light 221 can be produced by a laser or set of laser as pulsed radiation source 201. Lasers are able to produce light that is of high intensity, narrow wavelength, short pulse duration, uniform intensity, and stable intensity. It should be appreciated that pulsed radiation source 201 can include a plurality of individual sources, e.g., first pulsed radiation source 201.1, second pulsed radiation source 201.2, . . . , n-th pulsed radiation source 201.n (wherein n is an arbitrary integer), that individually produce their own coherent light 221 (e.g., first coherent light 221.1, second coherent light 221.2, . . . , n-th coherent light 221.n (wherein n is an arbitrary integer)) under individual dynamic adjustment by separate pulsed radiation source control signal 226 (e.g., first pulsed radiation source control signal 226.1, second pulsed radiation source control signal 226.2, . . . , n-th pulsed radiation source control signal 226.n (wherein n is an arbitrary integer)).

Field ions 222 are ions that are made from atom probe sample 202 by applying an electric field and/or heating and/or photoionization-based mechanisms. Field ions 222 can have a high kinetic energy. They can create a mass spectrum or time-of-flight spectrum. The spectra can be used to identify the elements present in a sample and to determine their relative concentrations. Field ions can also be used to create a three-dimensional point cloud map of the isotopic identity and location of the original atoms in the atom probe sample 202. These three-dimensional point cloud maps can be used to study the structure of materials and to identify defects and impurities. It should be appreciated that field ions 222 are ions that are ejected from atom probe sample 202 by the combination of high voltage bias 228 and pulsed radiation source 201. Pulsed radiation source 201 produces first coherent light 221.1 and second coherent light 221.2 of a wavelength, pulse rate, pulse duration, pulse duty cycle, or optical fluence that is adjusted by the first pulsed radiation source control signal 226 and the second pulsed radiation source control signal 226. The coherent light is communicated to atom probe sample 202, where it causes the evaporation of ions from the surface of the sample. Emitted ions 222 are then detected by the ion detector 203 and their time-of-arrival, kinetic energy, or position is recorded. This information is used to create a three-dimensional point cloud dataset of atom probe sample 202. It should be appreciated that pulsed radiation source 201 can include a plurality of individual sources, e.g., first pulsed radiation source 201.1, second pulsed radiation source 201.2, . . . , n-th pulsed radiation source 201.n (wherein n is an arbitrary integer), that individually produce their own coherent light 221 (e.g., first coherent light 221.1, second coherent light 221.2, . . . , n-th coherent light 221.n (wherein n is an arbitrary integer)) under individual dynamic adjustment by separate pulsed radiation source control signal 226 (e.g., first pulsed radiation source control signal 226.1, second pulsed radiation source control signal 226.2, . . . , n-th pulsed radiation source control signal 226.n (wherein n is an arbitrary integer)) so that a plurality of different species of ions (e.g., first emitted ions 222.1, second emitted ions 222.2, . . . , n-th emitted ions 222.n (wherein n is an arbitrary integer)) are produced from atom probe sample 202 interacting atomic species-selectively with differing wavelengths (among other properties) of lights 221.

Ion signal 224 is a time-dependent signal that is produced by ion detector 203 as a function of the time-of-arrival, kinetic energy, or position of the first emitted ions 222 and second emitted ions 222 arriving at ion detector 203 after atom probe sample 202 is subjected to first coherent light 221 and second coherent light 221 in the presence of an external electric field produced by high voltage bias 228. Ion signal 224 can be used to determine the composition and location of atoms in atom probe sample 202. Ion signal 224 can be used to determine the composition of atom probe sample 202 by measuring the time-of-flight of the ions in the ion signal. Ion signal 224 can also be used to determine the location of atoms in atom probe sample 202 by measuring the position of the ion on the detector.

Pulsed radiation source control signal 226 is a signal that is used to control pulsed radiation source 201. Pulsed radiation source 201 produces coherent light 221, which is used to evaporate atoms from atom probe sample 202. Pulsed radiation source control signal 226 controls the wavelength, pulse rate, pulse duration, pulse duty cycle, or optical fluence of coherent light 221. Pulsed radiation source control signal 226 is generated by analyzer 205 based on ion signal 224. Ion signal 224 is a signal that is generated by ion detector 203. Ion detector 203 detects emitted ions 222 that are emitted from atom probe sample 202. The analyzer 205 uses ion signal 224 to determine the number of ions that are emitted from atom probe sample 202 per time or solid angle or the total number of ions that are emitted from atom probe sample 202. The analyzer 205 then uses this information to generate pulsed radiation source control signal 226. Pulsed radiation source control signal 226 is used to control pulsed radiation source 201, which produces coherent light 221, which is used to evaporate atoms from atom probe sample 202. Pulsed radiation source control signal 226 is a dynamic signal that is constantly being adjusted by analyzer 205 based on ion signal 224. This allows analyzer 205 to optimize the number of ions that are emitted from atom probe sample 202 (e.g., per time or solid angle or the total number of ions that are emitted from atom probe sample 202). Pulsed radiation source control signal 226 has a number of properties that make it suited for use in an atom probe tomograph. Pulsed radiation source control signal 226 is a dynamic signal that can be constantly adjusted by the analyzer 205 based on ion signal 224 and high voltage bias 228. This allows the analyzer 205 to optimize the number of ions that are emitted from atom probe sample 202 per time or solid angle or the total number of ions that are emitted from atom probe sample 202. Pulsed radiation source control signal 226 is a precise signal that can be used to control the wavelength, pulse rate, pulse duration, pulse duty cycle, or optical fluence of coherent light 221. It should be appreciated that pulsed radiation source 201 can include a plurality of individual sources, e.g., first pulsed radiation source 201.1, second pulsed radiation source 201.2, . . . , n-th pulsed radiation source 201.n (wherein n is an arbitrary integer), that individually produce their own coherent light 221 (e.g., first coherent light 221.1, second coherent light 221.2, . . . , n-th coherent light 221.n (wherein n is an arbitrary integer)) under individual dynamic adjustment by separate pulsed radiation source control signal 226 (e.g., first pulsed radiation source control signal 226.1, second pulsed radiation source control signal 226.2, . . . , n-th pulsed radiation source control signal 226.n (wherein n is an arbitrary integer)) so that a plurality of different species of ions (e.g., first emitted ions 222.1, second emitted ions 222.2, . . . , n-th emitted ions 222.n (wherein n is an arbitrary integer)) is produced from atom probe sample 202 interacting atomic species-selectively with differing wavelengths (among other properties) of lights 221. Accordingly, it should be appreciated that analyzer 205 produces a plurality of pulsed radiation source control signal 226 to accommodate operating conditions per the chemical species included in atom probe sample 202.

High voltage bias control signal 227 is a feedback control system signal that dynamically adjusts high voltage bias 228 applied to atom probe sample 202 through electrical contact with sample stage 209 to optimize the number of first emitted ions 222 and second emitted ions 222 produced per time or solid angle or the total number of first emitted ions 222 and second emitted ions 222. Analyzer 205 receives ion signal 224 from ion detector 203, which contains information about the number of first emitted ions 222 and second emitted ions 222 produced per time or solid angle or the total number of first emitted ions 222 and second emitted ions 222. Analyzer 205 then uses this information to dynamically adjust high voltage bias 228 via high voltage bias control signal 227 to optimize the number of first emitted ions 222 and second emitted ions 222 produced per time or solid angle or the total number of first emitted ions 222 and second emitted ions 222. High voltage bias control signal 227 can be implemented in a variety of ways such as a feedback loop that includes a proportional-integral-derivative (PID) controller in analyzer 205.

High voltage bias 228 is voltage applied to atom probe sample 202 through electrical contact with atom probe sample stage 209 to create an electric field that both contributes to field ion emission and accelerates emitted field emitted ions 222 from atom probe sample 202 toward ion detector 203. The magnitude of high voltage bias 228 is typically in the range from 500 V to 15 kV. High voltage bias 228 can be applied either continuously, pulsed, or a combination of the two (e.g., a voltage pulse superimposed on a constant voltage bias). The pulse width, shape, and repetition rate of high voltage bias 228 can be varied to optimize the performance of the atom probe. High voltage bias 228 has a number of important effects on the performance of the atom probe. High voltage bias 228 can increase the number of emitted ions 222 that are emitted from atom probe sample 202 by decreasing the activation energy barrier for field ion emission.

Electron beam 229 is produced by electron source 207, communicated from electron source 207 to atom probe sample 202, received by atom probe sample 202, and produces scattered electrons 230 from interaction with atom probe sample 202. Electron beam 229 can be a parallel or convergent beam of electrons that is focused on atom probe sample 202. Electron beam 229 can be generated by thermionic or field emission sources (e.g., LaB₆, Schottky field emitter, and the like). The electrons are accelerated by a voltage of typically 1 kilovolts to 300 kilovolts. Electron beam 229 can be focused by a series of magnetic or electrostatic lenses. Electron beam 229 cam be static or scanned across atom probe sample 202 by a set of deflection coils. Electron beam 229 interacts with the atoms in atom probe sample 202. The electrons are scattered as scattered electrons 230 by the atoms in atom probe sample 202. Scattered electrons 230 are detected by electron detector 208. Electron detector 208 converts the scattered electrons into electrical signal (electron data 216) that can be amplified and processed by analyzer 205. Analyzer 205 uses electron data 216 to calculate the shape or determine the crystallographic phase of the atom probe sample 202.

Scattered electrons 230 are produced by the interaction of electron beam 229 with atom probe sample 202. The angle of scattering of scattered electrons 230 can be used to determine the crystallographic phase in atom probe sample 202. Scattered electrons 230 can be used to create a two-dimensional image of atom probe sample 202, e.g., a secondary electron micrograph.

Dynamic multi-wavelength and sample voltage atom probe tomograph feedback control system 200 can be made in various ways. It should be appreciated that dynamic multi-wavelength and sample voltage atom probe tomograph feedback control system 200 includes a number of optical, electrical, or mechanical components, wherein such components can be interconnected and placed in communication (e.g., optical communication, electrical communication, mechanical communication, fluid communication, and the like) by physical, chemical, optical, or free-space interconnects. The components can be disposed on mounts that can be disposed on a bulkhead for alignment or physical compartmentalization.

In an embodiment, a process for making and assembling dynamic multi-wavelength and sample voltage atom probe tomograph feedback control system 200 includes various steps. The process includes creating a vacuum chamber. This can be done by using a pump to remove the air from a chamber. The chamber should be large enough to accommodate the atom probe sample and the ion detector. The process can include creating a sample holder. This can be done by using a piece of metal, ceramic, or other vacuum-compatible material. The sample holder should be small enough to fit inside the atom probe sample chamber and should have a hole in the center for the atom probe sample to fit through. The process can include creating the atom probe sample, e.g., by using a variety of methods, such as ion beam milling or electrochemical etching. The atom probe sample should be small enough to fit inside the sample holder and should be made of a material that is compatible with the atom probe tomography process. The process can include providing the pulsed radiation source. The pulsed radiation source should produce light of a wavelength that is compatible with the atom probe tomography process. The process can include creating the ion detector, e.g., by using a variety of methods, such as a time-of-flight mass spectrometer, a microchannel plate, delay line detector, and the like. The ion detector should be able to detect ions of a variety of masses and energies. The process can include providing the high voltage supply. The process can include creating the analyzer, e.g., by using a computer or a software program. The analyzer should be able to analyze the data from the ion detector and create a three-dimensional point cloud dataset of the atom probe sample.

In an embodiment, a process for making dynamic multi-wavelength and sample voltage atom probe tomograph feedback control system 200 includes providing a vacuum chamber; and connecting radiation source to vacuum chamber, wherein a coupler can be used. Optics may be used to steer and focus the radiation source(s) independently from each other. Additionally, one can control the intensity of each individual wavelength or band of wavelengths individually. A delay can occur in the timing of the individual radiation pulses relative to each other or some absolute t0. The individual optics can be mounted in the chamber or exterior to the chamber. A specimen stage is disposed in the chamber, and a specimen is disposed on the stage. The ion detector is attached in the chamber. One connects a high voltage supply to the specimen stage. The high voltage supply can be connected to an extraction electrode, counter electrode, or the ion detector. A potential drop occurs between the biased specimen and the detector. The specimen is biased positively relative to the extraction electrode or the detector such that ions are electrostatically drawn from the specimen and impinge on the detector. An analyzer is connected to the chamber in electrical communication with the high voltage supply, specimen stage, and radiation sources.

Dynamic multi-wavelength and sample voltage atom probe tomograph feedback control system 200 has numerous expected advantageous and may also have unexpected benefits and uses. In an embodiment, a process for dynamically adjusting optical wavelengths and sample voltage in real-time with atom probe tomography feedback includes: providing a sample; providing a pulsed radiation source in optical communication with the sample; providing an ion detector in fluid communication with the sample; providing a high voltage supply in electrical communication with the sample; and providing an analyzer in electrical communication with the pulsed radiation source, the ion detector, and the high voltage supply. In an embodiment, the pulsed radiation source produces first coherent light and second coherent light. In an embodiment, the first coherent light and the second coherent light have different wavelengths. In an embodiment, the first coherent light and the second coherent light have different pulse rates. In an embodiment, the first coherent light and the second coherent light have different pulse durations. In an embodiment, the first coherent light and the second coherent light have different pulse duty cycles. In an embodiment, the first coherent light and the second coherent light have different optical fluences. In an embodiment, the ion detector detects first emitted ions and second emitted ions from the sample. In an embodiment, the first emitted ions and the second emitted ions are produced by the sample being subjected to the first coherent light and the second coherent light in the presence of an external electric field produced by the high voltage supply. In an embodiment, the high voltage supply subjects the sample to the external electric field by biasing the sample relative to a counter electrode or the ion detector. In an embodiment, the analyzer receives ion signal from the ion detector and dynamically produces a first pulsed radiation source control signal, a second pulsed radiation source control signal, and a high voltage bias control based on the ion signal. In an embodiment, the number of first emitted ions and second emitted ions produced per time or solid angle or the total number of first emitted ions and second emitted ions is dynamically optimized by the first pulsed radiation source control signal, the second pulsed radiation source control signal, and the high voltage bias control. In an embodiment, the analyzer continuously analyzes ion signal from the ion detector.

Dynamic multi-wavelength and sample voltage atom probe tomograph feedback control system 200 can be used to create a three-dimensional point cloud map of type and location of atoms in a material. The process begins by preparing the sample. This may involve cutting the sample into a thin slice, or it may involve electrochemical etching or focused ion beam milling. The sample is then placed in the atom probe tomograph, and a high voltage is applied to it. It is subject to first radiation source and/or second radiation source, etc. This causes atoms to be ejected from the sample and ionized, e.g., one at a time. The ions are then detected by an ion detector, and their time-of-flight and location on the detector is measured. This information is used to reconstruct the three-dimensional atomic point cloud dataset of the sample. Dynamic multi-wavelength and sample voltage atom probe tomograph feedback control system 200 can be used to improve the quality of the three-dimensional map by adjusting the wavelength of the lights (221.1, 221.2) used to eject ions from the sample. This can be done by adjusting pulsed radiation source control signal 226. The process conditions for using dynamic multi-wavelength and sample voltage atom probe tomograph feedback control system 200 can vary depending on the material being analyzed.

In an embodiment, a process for dynamically adjusting optical wavelengths and sample voltage in real-time with atom probe tomography feedback includes: producing radiation from radiation source(s) λ1, λ2, . . . , λi; subjecting the sample to radiation sources; subjecting the sample to increasing high voltage until ions are emitted; evaporating ions from the specimen surface; detecting ions on the ion detector as a function of time of arrival, kinetic energy, or position on the detector; analyzing data from ion detector and high voltage supply continuously; optimizing relative contribution of wavelengths λi intensity and time delay or duty cycle to maximize or minimize some specimen response function or figure of merit, wherein figures of merit can include extraction voltage, ion detection rate, ion detection rate per solid angle, background signal (noise), multiple hit signal, or single hit signal; and optimizing continuously as atoms (as ions) are removed from the specimen and the specimen is eroded thus progressively revealing the constituent elements, phases, materials, and compounds.

In an embodiment, dynamic multi-wavelength and sample voltage atom probe tomograph feedback control system with real-time with atom probe tomography feedback 200 can include the properties, functionality, hardware, and process steps described herein and embodied in any of the following non-exhaustive list:
a process (e.g., a computer-implemented method including various steps; or a method carried out by a computer including various steps);
an apparatus, device, or system (e.g., a data processing apparatus, device, or system including means for carrying out such various steps of the process; a data processing apparatus, device, or system including means for carrying out various steps; a data processing apparatus, device, or system including a processor adapted to or configured to perform such various steps of the process);
a computer program product (e.g., a computer program product including instructions which, when the program is executed by a computer, cause the computer to carry out such various steps of the process; a computer program product including instructions which, when the program is executed by a computer, cause the computer to carry out various steps);
a computer-readable storage medium or data carrier (e.g., a computer-readable storage medium including instructions which, when executed by a computer, cause the computer to carry out such various steps of the process; a computer-readable storage medium including instructions which, when executed by a computer, cause the computer to carry out various steps; a computer-readable data carrier having stored thereon the computer program product; a data carrier signal carrying the computer program product);a computer program product including comprising instructions which, when the program is executed by a first computer, cause the first computer to encode data by performing certain steps and to transmit the encoded data to a second computer; or
a computer program product including instructions which, when the program is executed by a second computer, cause the second computer to receive encoded data from a first computer and decode the received data by performing certain steps. This may include a neural network learning algorithm, or other machine learning or artificial intelligence-based analysis methods.

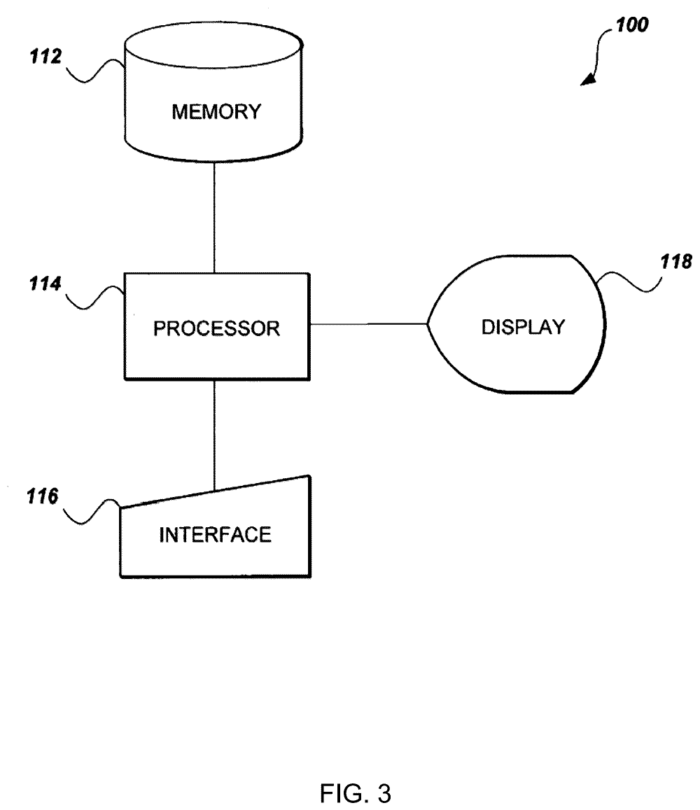

It should be understood that the calculations may be performed by any suitable computer system, such as that diagrammatically shown in FIG. 3. Data is entered into system 100 via any suitable type of user interface 116, and may be stored in memory 112, which may be any suitable type of computer readable and programmable memory and is preferably a non-transitory, computer readable storage medium. Calculations are performed by processor 114, which may be any suitable type of computer processor and may be displayed to the user on display 118, which may be any suitable type of computer display.

Processor 114 may be associated with, or incorporated into, any suitable type of computing device, for example, a personal computer or a programmable logic controller. The display 118, the processor 114, the memory 112 and any associated computer readable recording media are in communication with one another by any suitable type of data bus, as is well known in the art.

Examples of computer-readable recording media include non-transitory storage media, a magnetic recording apparatus, an optical disk, a magneto-optical disk, and/or a semiconductor memory.

Dynamic multi-wavelength and sample voltage atom probe tomograph feedback control system 200 has several potential advantages over conventional systems. The ability to dynamically adjust the optical wavelengths with coordinated adjustments to sample voltage allows for more precise control of the atom probe tomography process. This can lead to improved data quality, increased sample survivability, and increased mass spectral resolution. The use of an electron beam to interact with the atom probe sample can provide additional information about the sample's shape during the process, leading to a more accurate spatial reconstruction. Dynamic multi-wavelength and sample voltage atom probe tomograph feedback control system 200 described herein can significantly improve the accuracy, resolution, and sample survivability of atom probe tomography. This could lead to a number of applications in materials science, biology, and other fields.

Conventional atom probe tomography technology uses a single wavelength pulsed laser to evaporate atoms from a sample, and then measures the time-of-flight of the emitted atoms to reconstruct the three-dimensional structure of the sample. However, such conventional systems have several disadvantages including a single pulsed radiation source used to trigger field ion evaporation, which may not be optimized for all of the different elements, phases, components, or materials in the atom probe sample. In addition, conventional atom probe tomography technology often leads to unacceptable sample fracture during analysis.

The articles and processes herein are illustrated further by the following Example, which are non-limiting.

### EXAMPLES

### Example 1

An atom probe tomograph (APT) is a powerful tool for the three-dimensional imaging of materials at the atomic scale. However, APT can be limited by the optical and thermophysical properties of the constituent elements, phases, substances, or materials in the atom probe sample 202. The dynamic multi-wavelength and sample voltage atom probe tomograph feedback control system 200 overcomes this limitation by dynamically adjusting the optical wavelengths and sample voltage in real-time with atom probe tomography feedback. This allows for optimization of field ion emission for any combination of atom probe sample 202 constituents, resulting in decreased sample fracture, increased accuracy, and precision in measurement of composition and atomic position.

In an embodiment, the dynamic multi-wavelength and sample voltage atom probe tomograph feedback control system 200 includes a pulsed radiation source 201, an ion detector 203, a high voltage supply 204, and an analyzer 205 with dynamically produced first pulsed radiation source control signal 226, second pulsed radiation source control signal 226, and high voltage bias control signal 227 based on feedback readings of ion signal 224. The pulsed radiation source 201 produces coherent light of at least two different wavelengths, λ1 and λ2. The ion detector 203 detects ions that are ejected from the sample by the combined action of the applied high voltage bias 228 and the coherent light 221. The analyzer 205 analyzes the ions detected by the ion detector 203 and adjusts the optical wavelengths and sample voltage in real-time to optimize the number of ions that are collected.

In another embodiment, the dynamic multi-wavelength and sample voltage atom probe tomograph feedback control system 200 includes an electron beam 229 and an electron detector 208. The electron beam 229 is produced by an electron source 207 and is communicated from the electron source 207 to the atom probe sample 202. The electron beam 229 interacts with the atom probe sample 202 and produces scattered electrons 230. The scattered electrons 230 are communicated from the atom probe sample 202 to the electron detector 208. The electron detector 208 detects the scattered electrons 230 and provides feedback to the analyzer 205. The analyzer 205 uses the feedback from the electron detector 208 to adjust the optical wavelengths and sample voltage in real-time to optimize the number of ions that are collected.

### Example 2

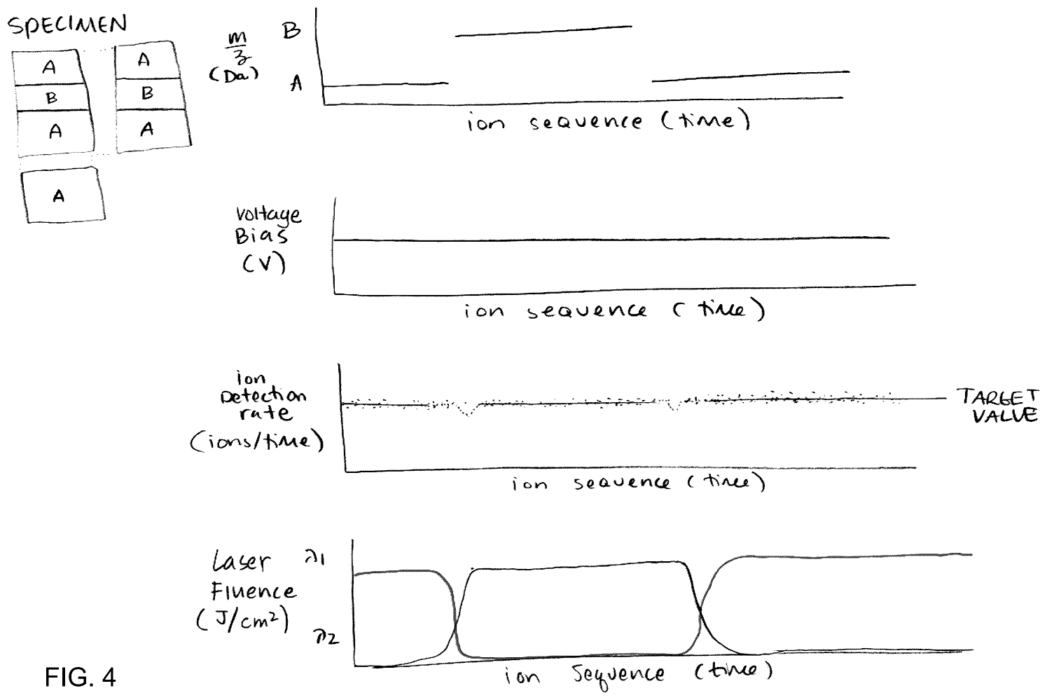

With reference to FIG. 4, the figure assumes a constant specimen radius for simplicity. Samples with varying radius are also, in general, permitted. The most common experiment performed in atom probe tomography is a detection rate control experiment. In such an experiment, the voltage is adjusted in order to maintain a constant detection rate as various elements, phases, compounds, and materials are eroded through field ion emission. FIG. 4 describes a constant detection rate experiment in a specimen with two phases. Instead of adjusting the voltage, the targeted ion detection rate is maintained by adjusting the fluence of two different wavelengths of coherent light 221.1 and 221.2. In FIG. 4, the target detection rate for component A can be best maintained with illumination from source 221.1 and the target detection rate for component B can be best maintained with illumination from source 221.2. The dynamic multi-wavelength and sample voltage atom probe tomograph feedback control system 200 will change the fluence of coherent light sources 221.1 and 222.2 in order to maintain the target detection rate as determined by the analyzer 205.

### Example 3

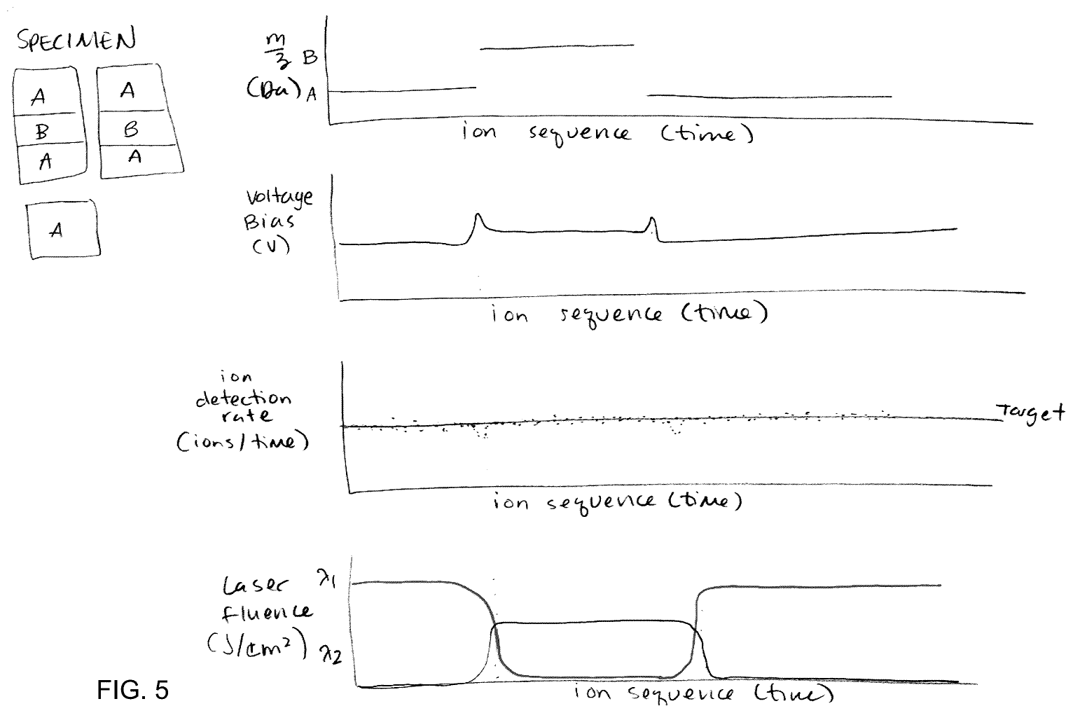

FIG. 5 assumes a constant specimen radius. In FIG. 5, the dynamic multi-wavelength and sample voltage atom probe tomograph feedback control system 200 attempts to minimize the high voltage bias 228 (subject to constraint) by varying the fluence of two different wavelengths of coherent light 221.1 and 221.2 (also subject to constraint). In this example, the voltage can be minimized in component A with coherent light wavelength 221.1, and the voltage can be minimized in component B with coherent light wavelength 221.2. The ion detection rate is allowed to adjust in response to changes in the high voltage bias 228 and the coherent light fluence 221.

### Example 4

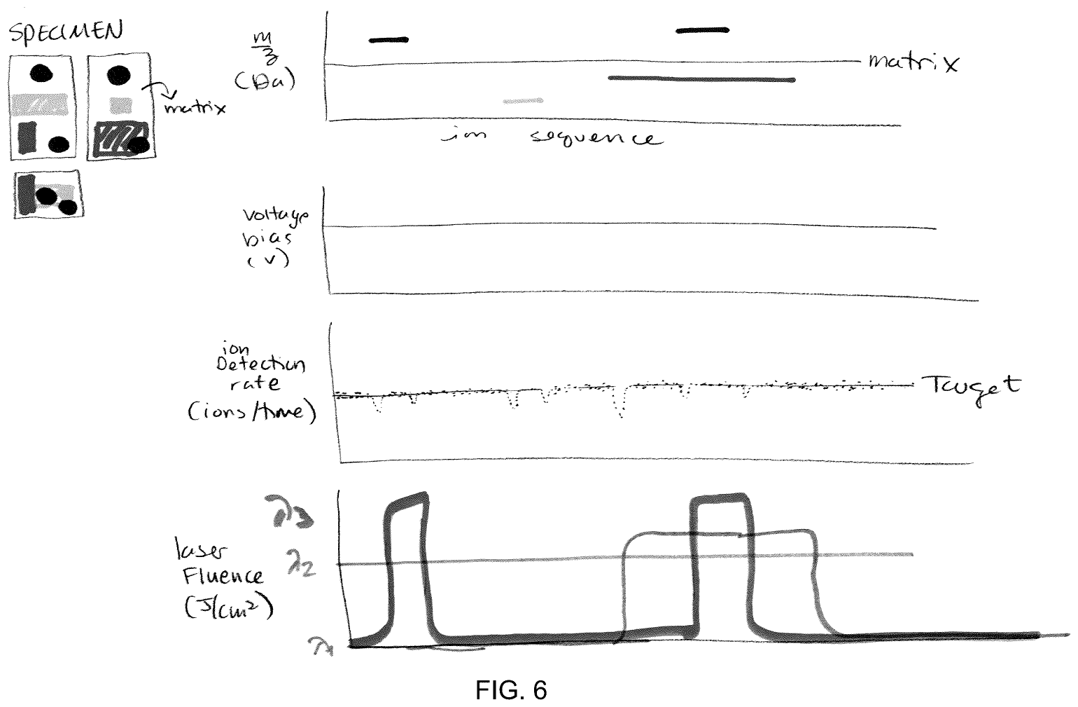

FIG. 6 assumes a constant specimen radius. The various components can be arbitrarily shaped, disposed, oriented, etc. They may or may not be symmetric. The need not be the same, nor uniform composition. In FIG. 6, the dynamic multi-wavelength and sample voltage atom probe tomograph feedback control system 200 attempts to maintain a target detection rate by simultaneously varying the fluence of three coherent light wavelengths 221.1, 221.2, and 221.3. In this example, the detection rate is optimized for the matrix and the yellow component using 221.2 (green). The detection rate is optimized for the blue component using wavelength 221.3 (orange). The detection rate is optimized for the red component using wavelength 221.1 (purple).

### Example 5

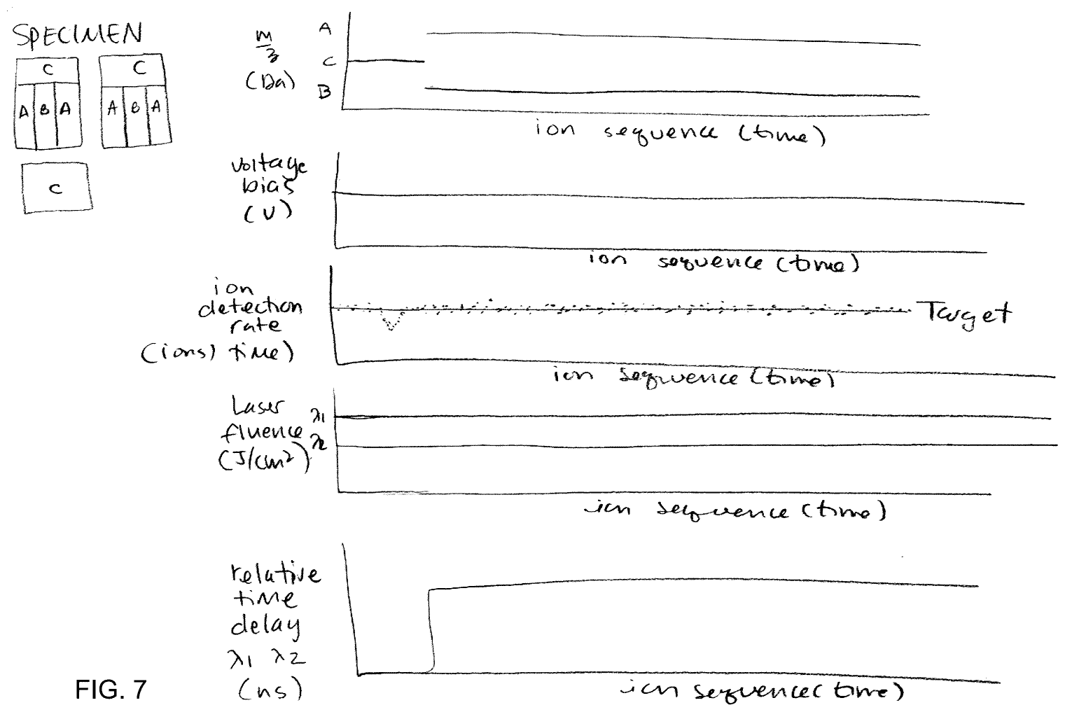

FIG. 7 assumes a constant specimen radius. In FIG. 7, the dynamic multi-wavelength and sample voltage atom probe tomograph feedback control system 200 attempts to maintain a target detection rate by simultaneously varying both the fluence of two different coherent light wavelengths 221.1 and 221.2 as well as the relative time delay between the two pulses. The ion detection rate is optimized when there is a finite time delay between 221.1 and 221.2.

### Example 6

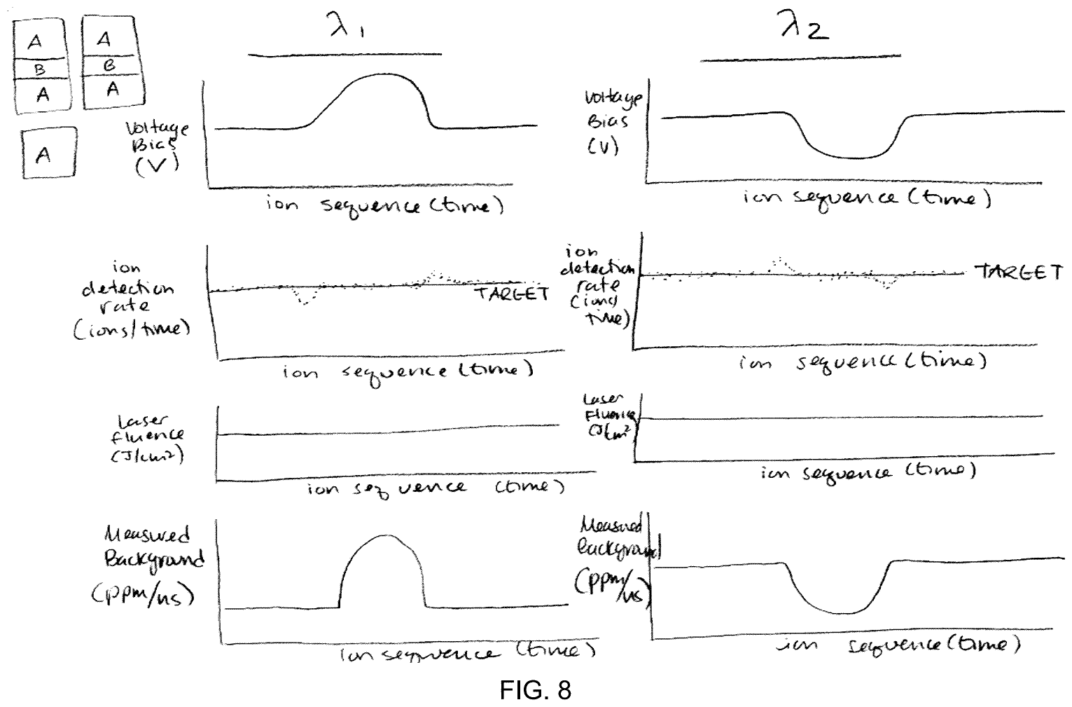

FIG. 8 shows exemplary data for a constant specimen radius. The specimen includes a multilayer thin film or similar, containing two different materials A and B with different evaporation fields. Two different constant evaporation rate experiments are performed and data are shown. In these experiments, the voltage is allowed to vary to maintain a nominal target detection rate for conducting atom probe tomography experiments. In the experiment using two selected wavelengths, λ1 and λ2, the specimen voltage increases to maintain the target detection rate as the experiment traverses through layer B, wherein material B has a higher evaporation field than material A when using wavelength λ1. Concomitant with an increase in the specimen voltage is an increase in the measured background signal while traversing the high evaporation field material B. In comparison, the same experiment is performed with a different laser wavelength λ2. In this case, the specimen voltage decreases in order to maintain a constant detection rate as the experiment traverses through layer B. Here, material B has a lower evaporation field than material A when using wavelength λ2. Similarly, the measured background signal decreases when traversing the apparently lower evaporation field material B when using wavelength 22.

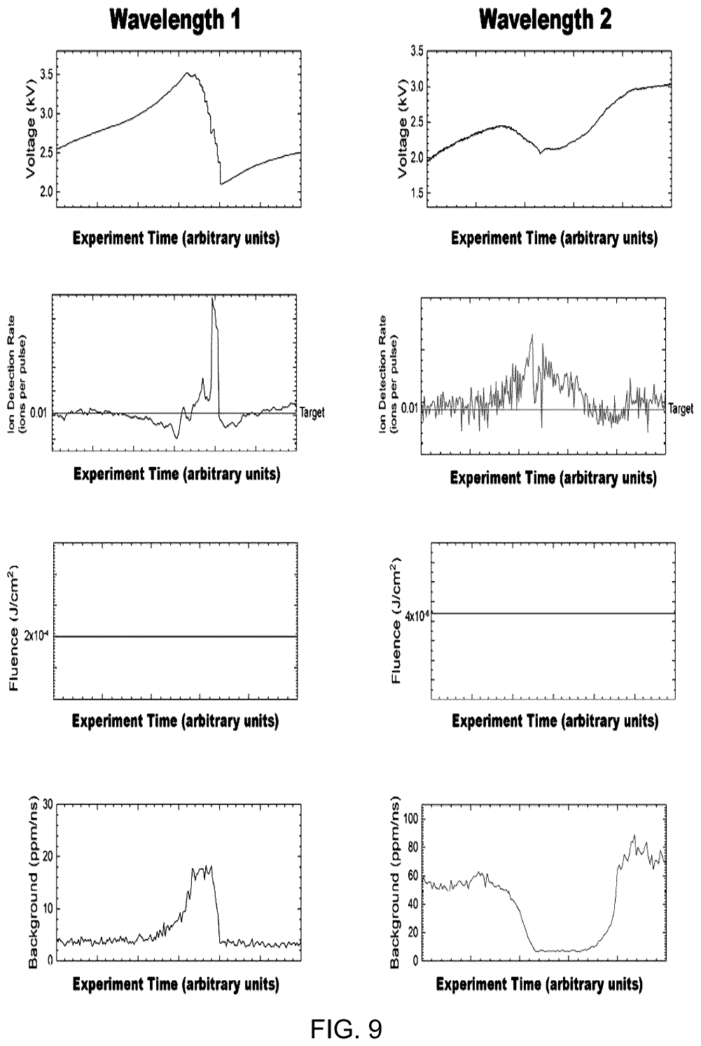

FIG. 9 shows results of analysis of experimental data using two different laser wavelengths in an experiment designed as described in FIG. 8. In this experiment, the specimens did not have a constant radius. Instead, the specimens had a radius with an approximately constant shank half-angle. This resulted in a smoothly varying increasing voltage curve as the specimen was traversed. In these experiments, the voltage was allowed to vary to maintain a nominal target detection rate. The experimental results in FIG. 9 demonstrated the benefit of applying two different laser wavelengths λ1 and λ2 to a material system as described in FIG. 8. In this experiment, for laser wavelength λ1 the material A had a lower evaporation field compared to material B. In order to maintain a constant target detection rate, the voltage increased as the specimen was traversed from the low evaporation field material A into the high evaporation field material B. Then the voltage decreased again in order to maintain a constant detection rate as the specimen was traversed from the high evaporation field material B into the lower evaporation field material A. The measured background signal was higher in material B. In contrast, when using a different laser wavelength λ2, material B had an apparently lower evaporation field compared to material A. This resulted in a decrease in voltage as the atom probe attempted to maintain a constant ion detection rate as the specimen traversed from the higher evaporation field material A into the lower evaporation field material B. Then, the voltage increased again as the specimen traversed from the low evaporation field material B into the higher evaporation field material A. Similarly, the measured background signal was higher in the higher evaporation field material A. Together these experiments showed that the specimen voltage required to maintain a constant ion detection rate and the measured background signal were not fundamental material properties, but rather were dependent on the laser wavelength used. These experiments showed the benefit of using two different laser wavelengths for performing atom probe experiments for samples such as shown in FIG. 4 and FIG. 5. In such an experiment, the dynamic multi-wavelength and sample voltage atom probe tomograph feedback control system can control, e.g., the relative fluence of laser wavelengths λ1 and λ2 to maintain a constant specimen voltage or minimize the measured background signal. The dynamic multi-wavelength and sample voltage atom probe tomograph feedback control system has turned on laser wavelength λ1 when material A was traversed and has turned on laser wavelength λ2 as material B was traversed to maintain a constant evaporation rate, minimize specimen voltage, or minimize background signal.

The processes described herein can be embodied in, and fully automated via, software code modules executed by a computing system that includes one or more general purpose computers or processors. The code modules can be stored in any type of non-transitory computer-readable medium or other computer storage device. Some or all the methods may alternatively be embodied in specialized computer hardware. In addition, the components referred to herein can be implemented in hardware, software, firmware, or a combination thereof.

Many other variations than those described herein can be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

Any logical blocks, modules, and algorithm elements described or used in connection with the embodiments disclosed herein can be implemented as electronic hardware, computer software, or combinations of both. To clearly illustrate this interchangeability of hardware and software, various illustrative components, blocks, modules, and elements have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described or used in connection with the embodiments disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer-executable instructions. In another embodiment, a processor includes an FPGA or other programmable device that performs logic operations without processing computer-executable instructions. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein can be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, or algorithm described in connection with the embodiments disclosed herein can be embodied directly in hardware, in a software module stored in one or more memory devices and executed by one or more processors, or in a combination of the two. A software module can reside in RAM memory, flash memory, ROM memory, EPROM memory, EEPROM memory, registers, hard disk, a removable disk, a CD-ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile.

While one or more embodiments have been shown and described, modifications and substitutions can be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are atomic percentages. The suffix(s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It can also be understood that, although the terms first, second, etc. are, in some instances, used herein to describe various elements, these elements should not be limited by these terms. For example, a first pulse could be termed a second pulse, and, similarly, a second pulse could be termed a first pulse, without departing from the scope of the various described embodiments. The first pulse and the second pulse are both pulses, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

### Parts List

dynamic multi-wavelength and sample voltage atom probe tomograph feedback control system 200
pulsed radiation source 201
atom probe sample 202
ion detector 203
high voltage supply 204
analyzer 205
vacuum chamber 206
electron source 207
electron detector 208
sample stage 209
coupler 210
ion optic 212
pulsed radiation source optic 213
camera 214
electron data 216
cryostat 217
timing electronics 218
vacuum gauge 219
vacuum valves 220
coherent light 221
emitted ions 222
ion signal 224
pulsed radiation source control signal 226
high voltage bias control signal 227
high voltage bias 228
electron beam 229
scattered electrons 230
dynamically adjusting optical wavelengths and sample voltage in real-time with atom probe tomography feedback//dynamically adjusts optical wavelengths and sample voltage in real-time with atom probe tomography feedback

What is claimed is:

1. A dynamic multi-wavelength and sample voltage atom probe tomograph feedback control system 200 for dynamically adjusting optical wavelengths and sample voltage in real-time with atom probe tomography feedback, the dynamic multi-wavelength and sample voltage atom probe tomograph feedback control system 200 comprising:
pulsed radiation source 201 in optical communication with atom probe sample 202 and in electrical communication with analyzer 205 and that receives first pulsed radiation source control signal 226 and second pulsed radiation source control signal 226 from analyzer 205, produces first coherent light 221 based on first pulsed radiation source control signal 226, produces second coherent light 221 based on second pulsed radiation source control signal 226, communicates first coherent light 221 to atom probe sample 202, communicates second coherent light 221 to atom probe sample 202, such that a wavelength, pulse rate, pulse duration, pulse duty cycle, or optical fluence of first coherent light 221 and second coherent light 221, or a relative time delay between first coherent light 221 and second coherent light 221, is adjusted by first pulsed radiation source control signal 226 and second pulsed radiation source control signal 226;
ion detector 203 in fluid communication with atom probe sample 202 and in electrical communication with analyzer 205 and that receives first emitted ions 222 and second emitted ions 222 from atom probe sample 202, produces ion signal 224 from first emitted ions 222 and second emitted ions 222, and communicates ion signal 224 to analyzer 205, such that ion detector 203 detects first emitted ions 222 and second emitted ions 222 as a function of a time-of-arrival, kinetic energy, or position of first emitted ions 222 and second emitted ions 222 arriving at ion detector 203 after atom probe sample 202 is subjected to first coherent light 221 and second coherent light 221 in the presence of an external electric field produced by high voltage bias 228;
high voltage supply 204 in electrical communication with atom probe sample 202 and analyzer 205 and that receives high voltage bias control 227 from analyzer 205, produces high voltage bias 228 from high voltage bias control 227, and communicates high voltage bias 228 to atom probe sample 202, such that high voltage bias 228 is dynamically adjusted by high voltage bias control 227 for optimizing, in combination with first pulsed radiation source control signal 226 and second pulsed radiation source control signal 226, the number of first emitted ions 222 and second emitted ions 222 produced per time or solid angle or the total number of first emitted ions 222 and second emitted ions 222, and high voltage supply 204 subjects atom probe sample 202 to the external electric field by biasing atom probe sample 202 relative to a counter electrode or ion detector 203; and
analyzer 205 in electrical communication with pulsed radiation source 201, ion detector 203, and high voltage supply 204 and that receives ion signal 224 from ion detector 203, dynamically produces first pulsed radiation source control signal 226, second pulsed radiation source control signal 226, and high voltage bias control 227 based on ion signal 224, such that the number of first emitted ions 222 and second emitted ions 222 produced per time or solid angle or the total number of first emitted ions 222 and second emitted ions 222 is dynamically optimized by first pulsed radiation source control signal 226, second pulsed radiation source control signal 226, and high voltage bias control 227, and analyzer 205 continuously analyze ion signal 224 from ion detector 203.

2. The dynamic multi-wavelength and sample voltage atom probe tomograph feedback control system 200 of claim 1, further comprising atom probe sample 202 in optical communication with pulsed radiation source 201 and in electrical communication with high voltage supply 204 and in fluid communication with ion detector 203 and that receives first coherent light 221 and second coherent light 221 from pulsed radiation source 201, receives high voltage bias 228 from high voltage supply 204 so that emitted ions 222 is voltage-biased with a high electric field strength between atom probe sample 202 and ion detector 203, produces first emitted ions 222 in response to interaction with first coherent light 221 in presence of high voltage bias 228, produces second emitted ions 222 in response to interaction with second coherent light 221 in presence of high voltage bias 228, and communicates first emitted ions 222 and second emitted ions 222 to ion detector 203, such that atom probe sample 202 is subjected to field ion emission where the number of first emitted ions 222 and second emitted ions 222 produced per time or solid angle or the total number of first emitted ions 222 and second emitted ions 222 is dynamically optimized by first pulsed radiation source control signal 226, second pulsed radiation source control signal 226, and high voltage bias control 227.

3. The dynamic multi-wavelength and sample voltage atom probe tomograph feedback control system 200 of claim 1, further comprising vacuum chamber 206 in which is disposed atom probe sample 202 and on which is disposed ion detector 203 and in optical communication with pulsed radiation source 201 and in mechanical communication with atom probe sample 202 and ion detector 203 and in electrical communication with high voltage supply 204 and analyzer 205 and that provides an evacuated gas atmosphere for atom probe sample 202 and ion detector 203.

4. The dynamic multi-wavelength and sample voltage atom probe tomograph feedback control system 200 of claim 1, further comprising:
electron source 207 that produces electron beam 229 and communicates electron beam 229 to atom probe sample 202, such that atom probe sample 202 produces scattered electrons 230 in response to receipt of electron beam 229, wherein scattered electrons 230 provides information about atom probe sample 202; and
electron detector 208 in electrical communication with analyzer 205 and that receives scattered electrons 230 from atom probe sample 202 in response to atom probe sample 202 received electron beam 229 from electron source 207, produces electron data 216 from scattered electrons 230, and communicates electron data 216 to analyzer 205.

5. The dynamic multi-wavelength and sample voltage atom probe tomograph feedback control system 200 of claim 1, further comprising sample stage 209 on which is disposed atom probe sample 202 and in mechanical communication with atom probe sample 202 and that provides for positional manipulation of atom probe sample 202 relative to ion detector 203, first coherent light 221, or second coherent light 221.

6. The dynamic multi-wavelength and sample voltage atom probe tomograph feedback control system 200 of claim 1, further comprising coupler 210 in optical communication with pulsed radiation source 201 and atom probe sample 202 and that receives first coherent light 221 and second coherent light 221 from pulsed radiation source 201 and communicates first coherent light 221 and second coherent light 221 to atom probe sample 202 in vacuum chamber 206 by optically coupling atom probe sample 202 to pulsed radiation source 201.

7. The dynamic multi-wavelength and sample voltage atom probe tomograph feedback control system 200 of claim 1, further comprising ion optic 212 that is interposed between atom probe sample 202 and ion detector 203, such that ion optic 212 extracts or focuses first emitted ions 222 and second emitted ions 222 from atom probe sample 202 and communicates first emitted ions 222 and second emitted ions 222 to ion detector 203, wherein ion optic 212 comprises an extraction electrode, a counter electrode, or Einzel lens.

8. The dynamic multi-wavelength and sample voltage atom probe tomograph feedback control system 200 of claim 1, further comprising pulsed radiation source optic 213 in optical communication with pulsed radiation source 201 and atom probe sample 202 and that receives first coherent light 221 and second coherent light 221 from pulsed radiation source 201 and communicates first coherent light 221 and second coherent light 221 to atom probe sample 202, such that pulsed radiation source optic 213 comprises a mirror, zone plate, or a lens.

9. The dynamic multi-wavelength and sample voltage atom probe tomograph feedback control system 200 of claim 4, further comprising electron data 216 that is communicated between electron detector 208 and analyzer 205 and comprises a position of arrival on detector electron detector 208 or scanning electron micrograph of scattered electrons 230 or a control signal to control electron detector 208.

10. The dynamic multi-wavelength and sample voltage atom probe tomograph feedback control system 200 of claim 1, further comprising cryostat 217 on which is disposed atom probe sample 202 and that is in thermal communication with atom probe sample 202, such that cools and temperature controls atom probe sample 202.

11. The dynamic multi-wavelength and sample voltage atom probe tomograph feedback control system 200 of claim 1, further comprising timing electronics 218 that are disposed in analyzer 205 and that comprise a time-to-digital convertor for synchronizing temporal performance of dynamic multi-wavelength and sample voltage atom probe tomograph feedback control system 200.

12. The dynamic multi-wavelength and sample voltage atom probe tomograph feedback control system 200 of claim 3, further comprising vacuum gauge 219 disposed on vacuum chamber 206 and in fluid communication with vacuum chamber 206 and that measures a pressure of vacuum chamber 206.

13. The dynamic multi-wavelength and sample voltage atom probe tomograph feedback control system 200 of claim 3, further comprising vacuum valves 220 disposed on vacuum chamber 206 and in mechanical communication with vacuum chamber 206 and that provides access to an interior of vacuum chamber 206 for arranging atom probe sample 202 in vacuum chamber 206.

14. The dynamic multi-wavelength and sample voltage atom probe tomograph feedback control system 200 of claim 1, further comprising coherent light 221 that is produced by pulsed radiation source 201 and communicated from pulsed radiation source 201 to atom probe sample 202 to produce emitted ions 222 from atoms of atom probe sample 202.

15. The dynamic multi-wavelength and sample voltage atom probe tomograph feedback control system 200 of claim 1, further comprising emitted ions 222 that are produced by atom probe sample 202 from atoms in atom probe sample 202 and communicated from atom probe sample 202 to ion detector 203.

16. The dynamic multi-wavelength and sample voltage atom probe tomograph feedback control system 200 of claim 1, further comprising ion signal 224 that is produced by ion detector 203 from receipt of emitted ions 222 by ion detector 203 and communicated from ion detector 203 to analyzer 205.

17. The dynamic multi-wavelength and sample voltage atom probe tomograph feedback control system 200 of claim 1, further comprising pulsed radiation source control signal 226 that is dynamically produced by analyzer 205 from analysis of ion signal 224, is communicated from analyzer 205 to pulsed radiation source 201, and controls the wavelength, pulse rate, pulse duration, pulse duty cycle, or optical fluence of first coherent light 221 and second coherent light 221, or a relative time delay between first coherent light 221 and second coherent light 221.

18. The dynamic multi-wavelength and sample voltage atom probe tomograph feedback control system 200 of claim 1, further comprising:
high voltage bias control 227 that is dynamically produced by analyzer 205 from analysis of ion signal 224, is communicated from analyzer 205 to high voltage supply 204, and controls the high voltage bias 228 supplied to atom probe sample 202 from high voltage supply 204; and
high voltage bias 228 that is produced by high voltage supply 204, communicated from high voltage supply 204 to atom probe sample 202, and received by atom probe sample 202 to electrically bias atom probe sample 202 and to create the electric field in which first emitted ions 222 and second emitted ions 222 are made.

19. The dynamic multi-wavelength and sample voltage atom probe tomograph feedback control system 200 of claim 4, further comprising:
electron beam 229 that is produced by electron source 207, communicated from electron source 207 to atom probe sample 202, received by atom probe sample 202, and produces scattered electrons 230 from interaction with atom probe sample 202; and
scattered electrons 230 that are produced by atom probe sample 202 from electron beam 229, communicated from atom probe sample 202 to electron detector 208, and received by electron detector 208.

20. A process of using a dynamic multi-wavelength and sample voltage atom probe tomograph feedback control system, comprising:
providing a sample;
providing a pulsed radiation source in optical communication with the sample;
providing an ion detector in fluid communication with the sample;
providing a high voltage supply in electrical communication with the sample; and
providing an analyzer in electrical communication with the pulsed radiation source, the ion detector, and the high voltage supply.

21. The process of claim 20, wherein the pulsed radiation source produces first coherent light and second coherent light.

22. The process of claim 21, wherein the first coherent light and the second coherent light have different wavelengths.

23. The process of claim 21, wherein the first coherent light and the second coherent light have different pulse rates.

24. The process of claim 21, wherein the first coherent light and the second coherent light have different pulse durations.

25. The process of claim 21, wherein the first coherent light and the second coherent light have different pulse duty cycles.

26. The process of claim 21, wherein the first coherent light and the second coherent light have different optical fluences.

27. The process of claim 20, wherein the ion detector detects first emitted ions and second emitted ions from the sample.

28. The process of claim 27, wherein the first emitted ions and the second emitted ions are produced by the sample being subjected to the first coherent light and the second coherent light in the presence of an external electric field produced by the high voltage supply.

29. The process of claim 20, wherein the high voltage supply subjects the sample to the external electric field by biasing the sample relative to a counter electrode or the ion detector.

30. The process of claim 20, wherein the analyzer receives ion signal from the ion detector and dynamically produces a first pulsed radiation source control signal, a second pulsed radiation source control signal, and a high voltage bias control based on the ion signal.

31. The process of claim 30, wherein the number of first emitted ions and second emitted ions produced per time or solid angle or the total number of first emitted ions and second emitted ions is dynamically optimized by the first pulsed radiation source control signal, the second pulsed radiation source control signal, and the high voltage bias control.

32. The process of claim 20, wherein the analyzer continuously analyzes ion signal from the ion detector.
